(19) United States
(12) Patent Application Publication
(10) Pub. No.: US 2011/0050249 A1
(43) Pub. Date: Mar. 3, 2011

(54) ELECTRIC CURRENT MEASURING DEVICE WITH INCREASED MECHANICAL STRENGTH FOR INSTALLATION

(75) Inventor: Shunichi Maeda, Chiryu-shi (JP)

(73) Assignee: DENSO CORPORATION, Kariya-city (JP)

(21) Appl. No.: 12/872,278

(22) Filed: Aug. 31, 2010

(30) Foreign Application Priority Data
Aug. 31, 2009 (JP) 2009-200047

(51) Int. Cl. G01R 27/28

(52) U.S. Cl. 324/649

(57) ABSTRACT

An electric current measuring device which measures current flowing from a storage battery, as installed, for example, in an engine compartment of automotive vehicles, to a harness. The current measuring device includes a bus bar with a first securement member and a second securement member, a current measuring circuit which works to measure current flowing through a resistor disposed between the first and second securement members, and a case located between the first and second securement members. The bus bar is made of a plate strip with a bend which has a bent cross section traversing a length of the plate strip, thereby increasing the degree of mechanical strength thereof (e.g., the first securement member) to withstand unwanted deformation or damage of the bus bar.

### CROSS REFERENCE TO RELATED DOCUMENT

The present application claims the benefit of priority of Japanese Patent Application No. 2009-200047 filed on Aug. 31, 2009, the disclosure of which is incorporated herein by reference.

### BACKGROUND OF THE INVENTION

1 Technical Field of the Invention

The present invention relates generally to an electric current measuring device which is to be installed, for example, in automotive vehicles such as passenger automobiles or autotrucks to sense or measure electric current being charged into or discharged from a storage battery mounted in the vehicle.

2 Background Art

Japanese Patent First Publication No. 2008-39571 teaches a current sensor equipped with a current measuring circuit which is disposed on a middle portion of a bus bar and retained inside a case. Some of automotive vehicles have two ground lines extending from a minus (−) terminal of a storage battery mounted in an engine compartment to both a body of the vehicle and an engine. The measurement of electric current flowing from the battery in such a type of vehicle requires installation of the current sensor near the minus terminal of the battery and monitoring of current flowing through the two ground lines.

The bus bar of the current sensor, as disclosed in the above publication, is made of a flat strip. Therefore, when the bus bar is joined to the terminal of the battery directly or indirectly through a bracket, it will be cantilevered by the terminal of the battery, which may result in an increased possibility of breakage thereof.

### SUMMARY OF THE INVENTION

It is therefore a principal object of the invention to provide an improved structure of a current measuring device designed to have mechanical strength great enough to withstand unwanted deformation or breakage thereof.

According to one aspect of the invention, there is provided an electric current measuring device designed to measure current flowing between a battery and a harness. The current measuring device comprises: (a) a first securement member which is to be secured electrically to a terminal of the battery; (b) a second securement member to which the harness is to be secured electrically; (c) a bus bar including the first and second securement members; (d) a resistor disposed between the first and second securement members, the resistor being formed one of integrally with or separately from the bus bar; (e) a circuit board having installed thereon a current measuring circuit which works to measure current flowing through the resistor as a function of the current flowing between the battery and the harness based on a potential difference between two points defined on a current flow path extending through the resistor; and (f) a case which is located between the first and second securement members and in which the resistor and the circuit board are disposed. The bus bar is made of a plate strip with a bend which has a bent cross section traversing a length of the plate strip. For example, the bend is formed by at least a side edge portion of the plate strip which is bent in a direction traversing the length of the plate strip. In the preferred mode of the invention, at least one of the first and second securement members of the bus bar has the bend.

The formation of the bend results in an increase in mechanical strength of the bus bar or the one of the first and second securement members. This minimizes undesirable deformation or damage of the bus bar or the case when the current measuring device is joined to the terminal of the battery. The one of the first and second securement portions also undergoes a less degree of deformation, thus resulting in a decrease in looseness of the one of the first and second securement portions when joined to the battery or the harness using, for example, a screw and also in stability of electric contact to the battery or the harness. This decreases the loss of supplying electric power to, for example, an engine starter to secure the startability of an engine mounted in an automotive vehicle. The decrease in deformation of the bus bar also permit the bus bar to be made of a thinner plate as long as it is required to secure the same degree of mechanical strength of the bus bar, thus permitting the current measuring device to be reduced in weight as a whole. The bend of the bus bar may be used to avoid an error in joining of the current measuring device to the battery and also used as a stopper to stop the current measuring device from turning undesirably. The bend of the bus bar may also serve to guide movement of the first securement portion, for example, in the case where the first securement portion is joined to the battery through an electrical lead or bracket. The formation of the bend results in an increased area of the bus bar from which the heat dissipates, thus improving the cooling ability of the bus bar without use of radiator fins. This results in a decrease in change in temperature of the bus bar, which improves the accuracy in measuring the current flowing from the battery or alternatively permits the current measuring device to be made by economical material as long as the current measurement accuracy is kept unchanged at a required level.

The bend of the bus bar may be defined by a C-shape in the cross section. This results in an increase in mechanical strength of the bus bar against bending thereof or vibrations acting thereon in a traversing direction, which minimizes the deformation or mechanical damage of the bus bar and the case.

The bend of the bus bar may alternatively be defined by an L-shape in the cross section. This shape is useful for avoiding the physical interference of the bus bar with any parts installed around the battery.

A portion of the bus bar extending outside the case and a portion of the bus bar embedded in the case are formed to have the bend.

The whole of the portion of the bus bar extending outside the case may be bent into a C- or L-shape to increase the mechanical strength thereof. The portion of the bus bar embedded in the case may also be bent into a C- or L-shape to increase the mechanical strength of a boundary portion of the bus bar (i.e., a portion of the bus bar placed in contact) between the case and the first securement portion, thereby minimizing a clearance around the boundary portion.

The bus bar may have a bottom wall and a side wall extending from an edge of the bottom wall. The bend of the bus bar may be defined by at least a portion of the bottom wall and the side wall. The portion of the bus bar embedded in the case may have a length greater than a height of the side wall that is a distance between the bottom wall of an edge of the side wall which is far from the bottom wall. This increases the mechanical strength of the boundary portion of the bus bar further.

The portion of the bus bar embedded in the case has a portion of the bend which is further bent. This further result in an increase in strength of a joint between the bus bar and the case.

The bend of the bus bar occupies an entire portion of the bus bar embedded in the case.

### BRIEF DESCRIPTION OF THE DRAWINGS

The present invention will be understood more fully from the detailed description given hereinbelow and from the accompanying drawings of the preferred embodiments of the invention, which, however, should not be taken to limit the invention to the specific embodiments but are for the purpose of explanation and understanding only.

In the drawings:

FIG. 1 is a partially sectional view which shows an electric current measuring device according to the invention which is placed in connection to a storage battery;

FIG. 2 is a side view of the current measuring device of FIG. 1;

FIG. 3 is a perspective view of the current measuring device of FIG. 1; and

FIG. 4 is a front view of the current measuring device of FIG. 1;

FIG. 5 is a circuit diaphragm which shows a circuit structure of the current measuring device of FIG. 1;

FIG. 6 is a front view which shows a modification of a bus bar installed in the current measuring device of FIG. 1; and

FIG. 7 is a perspective view which shows the second modification of a bus bar installed in the current measuring device of FIG. 1.

### DESCRIPTION OF THE PREFERRED EMBODIMENTS

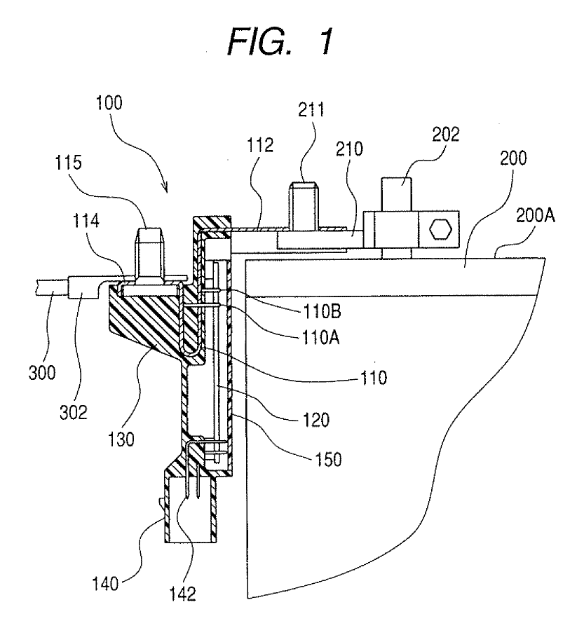

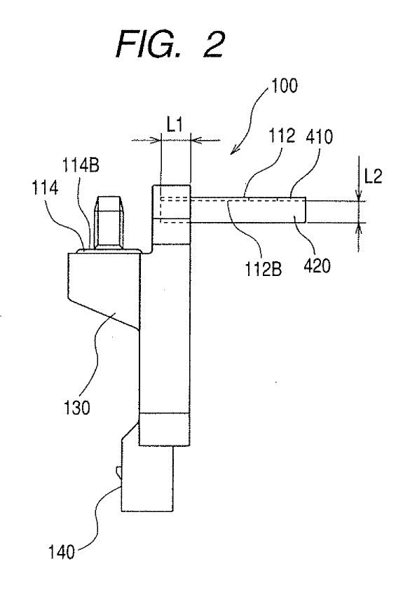

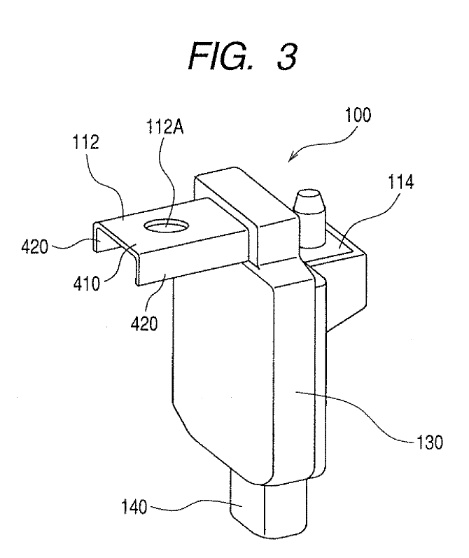

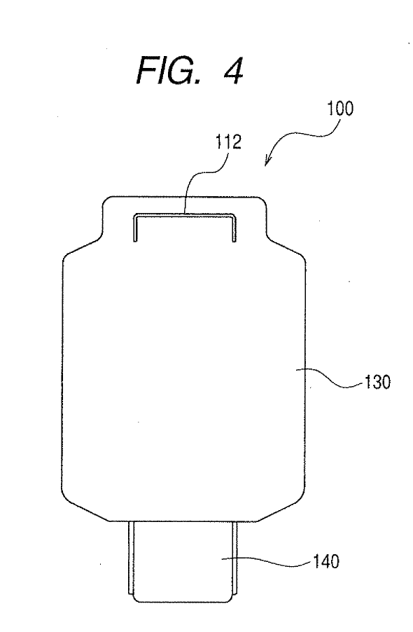

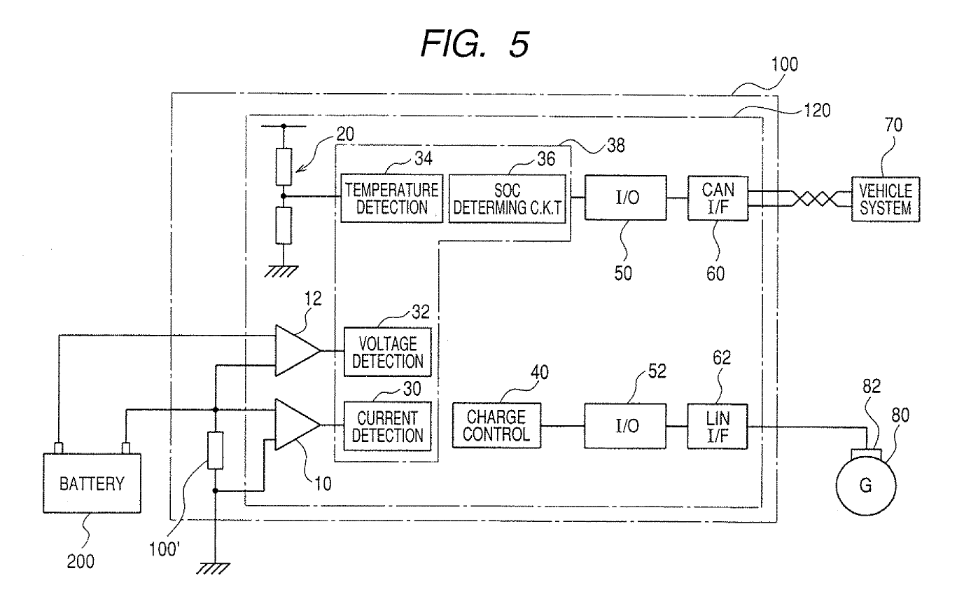

Referring to the drawings, wherein like reference numbers refer to like parts in several views, particularly to FIGS. 1 to 4, there is shown an electric current measuring device 100 according to the present invention. FIG. 1 is a partially sectional view which shows a structure of the current measuring device 100 installed on a storage battery 200 mounted in an engine compartment of an automotive vehicle. FIG. 2 is a side view of the current measuring device 100. FIG. 3 is a perspective view of the current measuring device 100. FIG. 4 is a front view of the current measuring device 100.

The current measuring device 100 includes a bus bar 110, a circuit board 120, a case 130, a connector 140, and a cover 150. The bus bar 110 is made of a conductive material and serves as a shunt resistor. The circuit board 120 has fabricated thereon a current measuring circuit which works to monitor a potential difference between two points across the bus bar 110 along a direction in which the current flows through the bus bar 110 to measure or determine electric current flowing through the bus bar 110. The case 130 stores the bus bar 110 and the circuit board 120 therein. The connector 140 has disposed therein a plurality of connector terminals 142 which electrically connect with the circuit board 120. The case 130 has a chamber in which the circuit board 120 is mounted. The cover 150 is fit in the case 130 to close the chamber.

The bus bar 110 is of a U-shape with a turn disposed within the case 130. The bus bar 110 has end portions one of which serves as a first securement portion 112 secured to the battery 200 to establish an electrical connection with the battery 200 and the other of which serves as a second securement portion 114 to which a harness 300 is secured electrically. The case 130 is substantially a rectangular parallelepiped and extends vertically, as viewed in FIG. 1, to have a given length. The case 130 is retained over one of side surfaces of the battery 200 which is closest to a terminal 202 of the battery 200 to which the current measuring device 100 is secured. The first and second securement portions 112 and 114, as can be seen from FIGS. 2 and 3, lie on opposed sides of a major body of the cover 130 and extend horizontally or perpendicular to the length of the cover 130 in opposite directions.

The first securement portion 112 is of a C-shape in cross section. In other words, the first securement portion 112 is, as clearly illustrated in FIG. 3, made up of a bottom and two upright side walls extending from ends of the bottom perpendicular to the bottom. The bottom has a circular through hole 112A formed therein. Referring back to FIG. 1, a metallic bracket 210 serving as a terminal clamp is fit on the minus (−) terminal 202 of the battery 200 to connect the first securement portion 112 of the bus bar 110 to the battery 200 electrically, thereby securing the current measuring device 100 to the battery 200. The metallic bracket 210 functions as an electric lead which establishes the electric connection between the current measuring device 100 and the battery 200. The metallic bracket 210 has on an end thereof the bolt 211 extending vertically of the metallic bracket 210. The installation of the first securement portion 112 to the metallic bracket 210 is achieved by inserting the bolt 211 of the metallic bracket 210 through an open end of the first securement portion 112 into the hole 112A, fastening a nut (not shown) onto the bolt 211 to retain the first securement portion 112 to the metallic bracket 210 firmly. The bottom (i.e., a strip) of the first securement portion 112 serves as a first joint surface 112B, as illustrated in FIG. 2, to which the metallic bracket 210 is joined firmly.

The second securement portion 114 of the bus bar 110 has formed in an end thereof a circular hole through which a bolt 115 is inserted. The harness 300 is joined electrically to the second securement portion 114. A terminal 302 is joined to the harness 300 and has a hole formed in an end portion thereof. The joint of the terminal 302 to the second securement portion 114 is achieved by inserting the bolt 115 installed on the second securement portion 113 into the hole of the terminal 302 and fastening a nut (not shown) onto the bolt 115 to fix the terminal 302 to the second securement portion 114. An upper surface of the second securement portion 114 serves as a second joint surface 114B, as illustrated in FIG. 2, to which the terminal 302 is joined firmly.

The case 130 is made of resin such as PPS (polyphenylene sulfide) which has greater electric insulation and thermal conductivity. A major portion of the bus bar 110 other than the first and second securement portions 112 and 114 is insert-molded with the resin in the case 130.

A sectional shape of the bus bar 100 will be described below.

The bus bar 110 is made of a conductive strip of a given length and has at least a portion which is of a substantially C-shape in transverse cross section. Specifically, the bus bar 100, as illustrated in FIGS. 3 and 4, has a C-shaped transverse cross section at least within a range including the first securement portion 113 made of a portion of the bus bar 110.

In other words, at least the first securement portion 112 is, as illustrated in FIG. 3, made up of a bottom 410 elongated in the lengthwise direction of the bus bar 100 and upright side walls 420 extending perpendicular to the bottom 410. Either one of the side walls 420 may be omitted. Specifically, the portion of the bus bar 110 having the C-shaped transverse cross section includes the first securement portion 112 exposed outside the case 130 and a portion of the bus bar 110 which continues from the first securement portion 112 and is embedded in the case 130. If the length of the embedded portion of the bus bar 110 in the lengthwise direction of the bus bar 110 is defined as L1, and the height of each of the side walls 420 (i.e., the distance between the inner surface of the bottom 410 and the side edge of the side wall 420 in a widthwise direction of the side wall 420) is defined as L2, the length L1 is selected to be greater than the height L2 (L1>L2).

FIG. 4 illustrates a circuit structure of the current measuring device 100 placed in connection to the battery 200. The current measuring device 100 has the circuit board 120 on which a differential amplifier 10, a differential amplifier 12, a temperature detector 20, a current detecting processor 30, a voltage detecting processor 32, a temperature detecting processor 34, a battery SOC (State-Of-Charge) determining circuit 36, a charge controller 40, communication I/O circuits 50 and 52, a CAN interface 60, and a LIN interface 62 are fabricated. The differential amplifier 10 is connected to ends of a shunt resistor 100′ formed by a portion of the bus bar 110. The differential amplifier 12 is connected to the plus (+) and minus (−) terminals of the battery 200. The CAN interface 60 works to transmit and receive data according to a CAN protocol. The LIN interface 62 works to transmit and receive data according to a LIN protocol. The differential amplifier 10 works to amplify voltage developed across the shunt resistor 100′. The current detecting processor 30 works to determine electric current flowing through the shunt resistor 100′ based on the voltage outputted from the differential amplifier 10 and provide an output indicative thereof as a function of electric current flowing from the battery 200 to the harness 300. The differential amplifier 10 and the current detecting processor 30 serve as the current measuring circuit. The differential amplifier 12 converts the voltage, as developed between the plus and minus terminals of the battery 200 (i.e. a battery voltage), into a selected voltage level. The voltage detecting processor 32 determines the battery voltage based on the voltage outputted from the differential amplifier 12. The temperature detector 20 is made of a voltage divider consisting of resistors and a thermistor. The thermistor has a resistance value which changes with ambient temperature to change a fraction of voltage applied to the voltage divider. The temperature detecting processor 34 monitors the fraction of voltage outputted from the temperature detector 20 to determine the temperature of the current measuring device 100 (i.e., the temperature of the battery 200). The battery SOC determining circuit 36 samples the outputs from the current detecting processor 30, the voltage detecting processor 32, and the temperature detecting processor 34 to produce a battery state-of-charge signal. The current detecting processor 30, the voltage detecting processor 32, and the temperature detecting processor 34, and the battery SOC determining circuit 36 work as a SOC sensor 38. The charge controller 40 samples the battery state-of-charge signal, as outputted from the battery SOC determining circuit 36 to control the electric generation (i.e., an output power) of an in-vehicle electric generator 80. Specifically, the charge controller 40 outputs a control signal to a generator controller 82 installed in the generator 80 through the communication I/O circuit 52 and the LIN interface 62 to control the power outputted by the generator 80. The battery state-of-charge signal, as outputted from the battery SOC determining circuit 36, is transmitted to a vehicle control system 70 through the communication I/O circuit 50 and the CAN interface 60. The vehicle control system 70 works to perform given integrated control tasks to control operations of the engine and various in-vehicle electric loads based on the state-of-charge of the battery 200.

The current detecting device 100 is, as described above, equipped with the bus bar 110 designed to partially have a rigidity-increased strip made up of a bottom wall and two side walls extending from the bottom wall (i.e., a C-shape in transverse cross section) within a range including the first securement portion 112. This results in an increase in mechanical strength of the bus bar 110 (i.e., the first securement portion 112 formed by an end portion of the bus bar 110), which will minimize the unwanted deformation or mechanical damage of the bus bar 110 or the case 130 when installed near the terminal 202 of the battery 200.

The decrease in deformation of the first securement portion 112 results in a decrease in looseness of the first securement portion 112 when joined to the bracket 210 through engagement of the bolt 211 with the nut and also in stability of electric contact of the first securement portion 112 to the terminal 202, thus decreasing the loss of supplying electric power to the engine starter (not shown) to secure the startability of the engine.

The decrease in deformation of the first securement portion 112 also permits the bus bar 110 to be made of a thinner plate as long as it is required to secure the same degree of mechanical strength of the bus bar 110, thus allowing the current measuring device 100 to be reduced in weight as a whole. The C-shape of the bus bar 110 (i.e., the first securement portion 112) may be used to avoid an error in installing the current measuring device 100 on the battery 200 and also used as a stopper to stop the first securement portion 112 from turning undesirably. The C-shape shape of the bus bar 110 also serves to guide relative movement of the bracket 210 to the first securement portion 112 when the first securement portion 112 is joined to the bracket 210 of the battery 200.

The C-shape of the bus bar 110 results in an increased area of the bus bar 110 from which the heat dissipates, thus improving the cooling ability of the bus bar 100 without use of radiator fins. This results in a decrease in change in temperature of the bus bar 110, which improves the accuracy in measuring the current flowing from the battery 200 or alternatively permits the current measuring device 100 to be made by economical material as long as the current measurement accuracy is kept unchanged at a required level.

The C-shape in transverse cross section of the bus bar 110 (i.e., the first securement portion 112) results in an increase in mechanical strength against bending thereof or vibrations acting thereon in a traversing direction, which minimizes the deformation or mechanical damage of the bus bar 110 and the case 130.

The whole of a portion (i.e., the first securement portion 112) of the bus bar 110 extending outside the case 130 may be bent into a C-shape to increase the mechanical strength thereof. A portion of the bus bar 110 embedded in the case 130 may also be bent into a C-shape to increase the mechanical strength of a boundary portion of the bus bar 110 (i.e., a portion of the bus bar 110 placed in contact) between the case 130 and the first securement portion 112, thereby minimizing a clearance around the boundary portion. The length L1 of the embedded portion of the bus bar 110 in the case 130 is, as described above, set greater than the height L2 of at least one of the side walls 420, thereby increasing the mechanical strength of the boundary portion of the bus bar 110 further.

While the present invention has been disclosed in terms of the preferred embodiment in order to facilitate better understanding thereof, it should be appreciated that the invention can be embodied in various ways without departing from the principle of the invention. Therefore, the invention should be understood to include all possible modifications to the shown embodiment which can be embodied without departing from the principle of the invention as set forth in the appended claims.

For instance, the current measuring device 100 is installed on the minus (−) terminal 202 of the battery 200, but may alternatively be joined to the plus terminal of the battery 200.

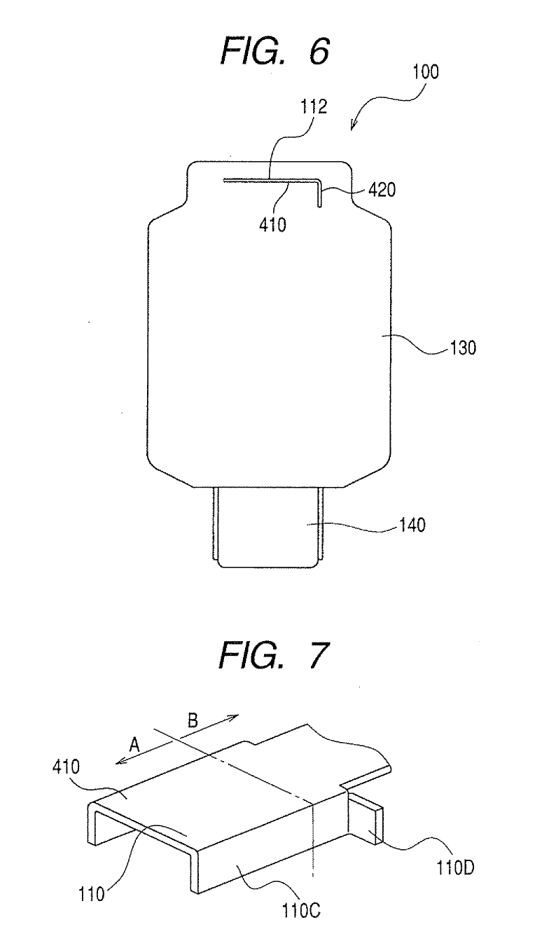

FIG. 6 illustrates a modification of the bus bar 110. Specifically, the bus bar 110 is bent into an L-shape made up of the bottom wall 410 and the side wall 420 extending vertically from either of sides of the bottom wall 410. This shape is useful for avoiding the physical interference of the bus bar 110 (i.e., the first securement portion 112) with any parts installed around the battery 200. The side wall 420 may be formed only outside the case 130 or extend into the case 130.

In the above embodiment, a portion of the bus bar 110 embedded in the case 130 has substantially the same configuration as the first securement portion 112 extending outside the case 130, but however, the embedded portion may, as illustrated in FIG. 7, be designed to have bends extending outwardly of the bus bar 110. FIG. 7 illustrates such a modification of the bus bar 110. In FIG. 7, “A” indicates a portion of the bus bar 110 (i.e., the first securement portion 112) extending outside the case 130. “B” indicates a portion of the bus bar 110 which continues from the first securement portion 112 and is embedded in the case 130. The bus bar 110 has, like in the first embodiment, the side walls 110C bent from the bottom wall 410. Each of the side walls 110C has a tab 110D bent outwardly or perpendicular to the length of the bus bar 110, thereby increasing the mechanical strength of a joint between the bus bar 110 and the case 130 and the bus bar 110 itself. Only either one of the side walls 110C may alternatively be formed to have the tab 110D.

The second securement portion 114 may also be bent, like the first securement portion 112, into the C- or L-shape in a transverse cross section thereof, as clearly illustrated in FIG. 3 or 6. Alternatively, only the second securement portion may be bent into the C- or L-shape.

The whole of a portion of the bus bar 110 extending inside the case 130 may also be bent into the C- or L-shape in a transverse cross section thereof. The bus bar 110 is made of a conductive material and easy to bend. The whole of the bus bar 110 may, therefore, be bent into the C- or L-shape in order to increase the mechanical strength thereof.

The chamber of the case 130 in which the circuit board 120 is placed is closed by the cover 150, but, may alternatively be filled with, for example, epoxy resin to encapsulate the circuit board 120.

The shunt resistor 100′ is formed by a portion of the bus bar 110, but may alternatively be separate from the bus bar 110 and disposed within a range where the potential difference between two points to determine the current flowing through the bus bar 110 is measured.

What is claimed is:

1. An electric current measuring device which measures current between a battery to a harness, comprising:
a first securement member which is to be secured electrically to a terminal of the battery;
a second securement member to which the harness is to be secured electrically;
a bus bar including the first and second securement members;
a resistor disposed between said first and second securement members, said resistor being formed one of integrally with or separately from said bus bar;
a circuit board having installed thereon a current measuring circuit which works to measure current flowing through said resistor as a function of the current flowing between the battery and the harness based on a potential difference between two points defined on a current flow path extending through said resistor; and
a case which is located between said first and second securement members and in which said resistor and said circuit board are disposed,
wherein said bus bar is made of a plate strip with a bend which has a bent cross section traversing a length of the plate strip.

2. An electric current measuring device as set forth in claim 1, wherein at least one of the first and second securement members of said bus bar has the bend.

3. An electric current measuring device as set forth in claim 1, wherein the bend of said bus bar is defined by a C-shape in the cross section.

4. An electric current measuring device as set forth in claim 1, wherein the bend of said bus bar is defined by an L-shape in the cross section.

5. An electric current measuring device as set forth in claim 1, wherein a portion of said bus bar extending outside said case and a portion of said bus bar embedded in the case have the bend.

6. An electric current measuring device as set forth in claim 5, wherein the bus bar has a bottom wall and a side wall extending from an edge of the bottom wall, wherein the bend of the bus bar is defined by at least a portion of the bottom wall and the side wall, and wherein the portion of said bus bar embedded in the case has a length greater than a height of the side wall that is a distance between the bottom wall of an edge of the side wall which is far from the bottom wall.

7. An electric current measuring device as set forth in claim 5, wherein the portion of said bus bar embedded in the case has a portion of the bend which is further bent.

8. An electric current measuring device as set forth in claim 1, wherein the bend of said bus bar occupies an entire portion of said bus bar embedded in the case.
